(19) United States
(12) Patent Application Publication
(10) Pub. No.: US 2022/0357735 A1
(43) Pub. Date: Nov. 10, 2022

(54) SYSTEM FOR MONITORING, CONTROLLING AND PREDICTING REQUIRED MAINTENANCE OF A FLUID SYSTEM AND METHOD OF IMPLEMENTING THE SAME

(71) Applicant: HAM-LET (ISRAEL - CANADA ) LTD., Nazareth Illit (IL)

(72) Inventors: Boris MARGOL, Nahariya (IL); Arik MIMRAN, Nazareth Illit (IL)

(21) Appl. No.: 17/624,410

(22) PCT Filed: Jul. 1, 2020
(86) PCT No.: PCT/IL2020/050733

§ 371 Date: Jan. 3, 2022

Related U.S. Application Data
(60) Provisional application No. 62/870,066, filed on Jul. 3, 2019.

(51) Int. Cl. G05B 23/02

(52) U.S. Cl. CPC G05B 23/0283; G05B 23/024; G05B 23/0281

(57) ABSTRACT

A system for monitoring, controlling and predicting required maintenance in fluid control circuits comprising: a plurality of local arrangements; each local arrangement further comprising: a plurality of elements characterized by monitorability, controllability and a combination thereof; a memory unit configured for storing data associated with monitoring said elements; a local data processing unit configured for at least one activity selected from the group consisting of: interrogating said memory unit, receiving said data associated with monitoring said elements, analyzing said data and predicting required maintenance of said elements and any combination thereof; a service provider server configured for duplicating at least one activity of said local data processing centers belonging to said local arrangements; said service provider server further configured for collecting detected operation patterns of said elements belonging to said local arrangements, statistically analyzing said collected operation patterns, indicating operation patterns referring to emergency and preventive maintenance.

### FIELD OF THE INVENTION

The present invention relates systems for managing fluid flows and, more particularly, to systems for monitoring, controlling and predicting required maintenance fluid flows.

### BACKGROUND OF THE INVENTION

CN 103399583A discloses a heterogeneous network communication-based water supply network monitoring and information service system which is characterized an equipment layer, a control layer, a dispatching layer and an information layer. The aforesaid network is used for implementing a monitoring method of the heterogeneous network communication-based water supply network monitoring and information service system.

The method comprises the following steps of firstly measuring a water supply network parameter and an equipment working condition parameter by a flow sensor, a pressure sensor, a pump/valve working condition sensor and the like, acquiring the parameters by a measurement and control module, and sending to a wireless communication gateway; then, sending to a management center server for processing, issuing a control command by the management center server according to processing results, firstly sending the control command to the wireless communication gateway and finally sending to the measurement and control module by a short range communication network to control corresponding control equipment; meanwhile, sending service information to an information service terminal by the management center server.

Distantly located fluid flow controlling devices require periodical inspection and maintenance. To alleviate the problem, the flow controlling devices can be distantly supervised. Specifically, all activity can be sensed in order to collect operation patterns statistically analyze the collected operation patterns and indicate operation patterns referring to emergency and preventive maintenance. Thus, there is a long and unmet need for providing a system for monitoring, controlling and predicting required maintenance fluid systems.

### SUMMARY OF THE INVENTION

It is hence one object of the invention to disclose a system for monitoring, controlling and predicting required maintenance in fluid control circuits. The aforesaid system comprises: (a) a plurality of local arrangements; each local arrangement further comprising: (i) at least one controlling element configured to control a fluid flow; (ii) at least one monitoring element configured to monitor an operation pattern of the at least controlling element; (iii) a memory unit configured for storing the operation pattern of the at least controlling element; (iv) a local data processing unit configured for at least one activity selected from the group consisting of: interrogating the memory unit, analyzing the operation pattern of the at least controlling element, recognize emergency events therewithin and predicting required maintenance of the at least one controlling element and any combination thereof; (b) a service provider server configured for duplicating at least one activity of the local data processing units belonging to the local arrangements; the service provider server further configured for collecting detected operation patterns of the controlling elements belonging to the local arrangements, statistically analyzing the collected operation patterns, indicating operation patterns referring to emergency and preventive maintenance.

It is a core purpose of the invention to provide at least one controlling element belonging to the local arrangements comprising an actuator configured to actuate the at least one controlling element; at least one of the local processing units belonging to the local arrangements and the service provider server are configured to generate commands to put into operation the actuator in response to recognizing the emergency events and to perform the preventive maintenance.

Another object of the invention is to disclose the controlling element which is a valve.

A further object of the invention is to disclose the monitoring element which is is a sensor configured for sensing activity of the controlling element.

A further object of the invention is to disclose each local arrangement comprising a transponder configured for transmitting the operation pattern sensed by the sensor to the memory unit and receiving the commands from the local data processing unit and service provider server.

A further object of the invention is to disclose the local data processing unit comprising a processor configured for interrogating the monitoring elements belonging to the local arrangements and receiving operation patterns and building a model of performance of the controlling elements by means of applying machine learning algorithm and preloaded training data in feedback therebetween.

According to a further embodiment of the present invention, the service provider server comprises a processor configured for interrogating the elements and receiving test data and building a hypothesis associated with performance of the elements by means of applying machine learning algorithm and preloaded training data in feedback therebetween; the processor is configured for collecting detected operation patterns of the elements belonging to the local arrangements, analyzing the collected operation patterns, indicating operation patterns referring to emergency and preventive maintenance.

A further object of the invention is to disclose the arrangements, memory units, local data processing units and service provider server interconnected therebetween by a protocol selected from the group consisting of a wired serial communication protocol, a wireless local network, a wireless personal area network, a nearfield communication network, a low power wide area network, a cellular network and any combination thereof.

A further object of the invention is to disclose a method of monitoring, controlling and predicting required in fluid control circuits. The aforesaid method comprising steps of: (a) providing a system further comprising: (i) a plurality of local arrangements; each local arrangement further comprising: (1) at least one controlling element configured to control a fluid flow; (2) at least one monitoring element configured to monitor an operation pattern of the at least controlling element; (3) a memory unit configured for storing the operation pattern of the at least controlling element; (4) a local data processing unit configured for at least one activity selected from the group consisting of: interrogating the memory unit, analyzing the operation pattern of the at least controlling element, recognize emergency events therewithin and predicting required maintenance of the at least one controlling element and any combination thereof; (i) a service provider server configured for duplicating at least one activity of the local data processing units belonging to the local arrangements; the service provider server further configured for collecting detected operation patterns of the controlling elements belonging to the local arrangements, statistically analyzing the collected operation patterns, indicating operation patterns referring to emergency and preventive maintenance; the at least one controlling element belonging to the local arrangements comprises an actuator configured to actuate the at least one controlling element; at least one of the local processing units belonging to the local arrangements and the service provider server are configured to generate commands to put into operation the actuator in response to recognizing the emergency events and to perform the preventive maintenance; (b) sensing activity of the elements; (c) transmitting sensed data to the memory unit; (d) interrogating the memory unit; (e) receiving the sensed data; (f) analyzing the sensed data; (g) predicting required maintenance; and (h) generating commands to put into operation the actuator in response to recognizing the emergency events and to perform the preventive maintenance.

A further object of the invention is to disclose the method comprising a step of indicating an emergency condition.

A further object of the invention is to disclose the method comprising a step of transmitting an emergency command of closing or opening the elements.

A further object of the invention is to disclose the method comprising a step of collecting detected operation patterns of the elements belonging to the local arrangements.

A further object of the invention is to disclose the method comprising a step of statistically analyzing the collected operation patterns.

A further object of the invention is to disclose the method comprising a step of indicating operation patterns referring to emergency and planning predictive maintenance.

### BRIEF DESCRIPTION OF THE DRAWINGS

In order to understand the invention and to see how it may be implemented in practice, a plurality of embodiments is adapted to now be described, by way of non-limiting example only, with reference to the accompanying drawings, in which

FIG. 1 is a schematic diagram of an element characterized by monitorability and controllability;

FIG. 2 is a schematic diagram of a system for monitoring, controlling and predicting required maintenance a fluid system;

FIG. 3 is an exploded view of a sensing valve; and

FIG. 4 is a cross-sectional view of a sensing valve.

### DETAILED DESCRIPTION OF THE INVENTION

The following description is provided, so as to enable any person skilled in the art to make use of said invention and sets forth the best modes contemplated by the inventor of carrying out this invention. Various modifications, however, are adapted to remain apparent to those skilled in the art, since the generic principles of the present invention have been defined specifically to provide a system for monitoring, controlling and predicting required maintenance in fluid control circuits and a method of implementing the same.

Fluid flow control elements such as valves, actuators, flow indicators, filters and strainers are used in many fields of technology. Often enough, the fluid flow control elements are difficult to approach for inspection and maintenance. In this case, it is very important to have objective information about operational integrity and performance characteristics in real time and take appropriate measures in emergency.

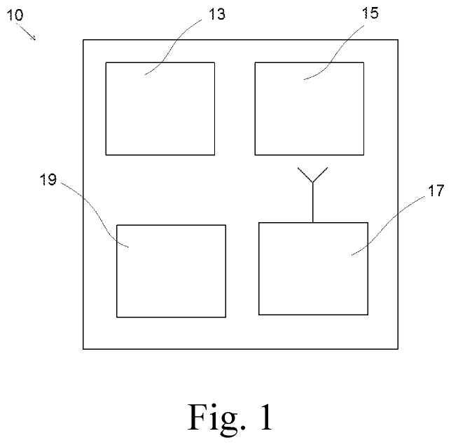

Reference is now made to FIG. 1 showing a schematic diagram of exemplary fluid flow control element 10. The term “control element” hereinafter refers to any fluid flow control device such as a valve, an actuator, a manifold and alike which has any manipulatable member configured for blocking or releasing a fluid flow. Element 10 is provided with sensor 13 and actuator 15 connected to transponder 17. Element 10 also provided with manually interrogatable memory unit 19 configured for logging the element activity. All activity pattern of element 10 is sensed by sensor 13. Any type of sensor including mechanical, acoustical, electromagnetic, thermal, relative humidity sensors or alike is in the scope of the present invention. The sensed element activity pattern is reported to a local data processing unit (described below) via transponder 17. The aforesaid local data processing unit in some cases can send commands to element 10 which are executed by actuator 15. These commands can concern blocking or releasing the fluid flow via element 10 or changing a flow rate therethrough. Data exchange between element 10 and other components of system can be carried out in wire or wireless manner. The element activity can be also manually interrogated from memory unit 19.

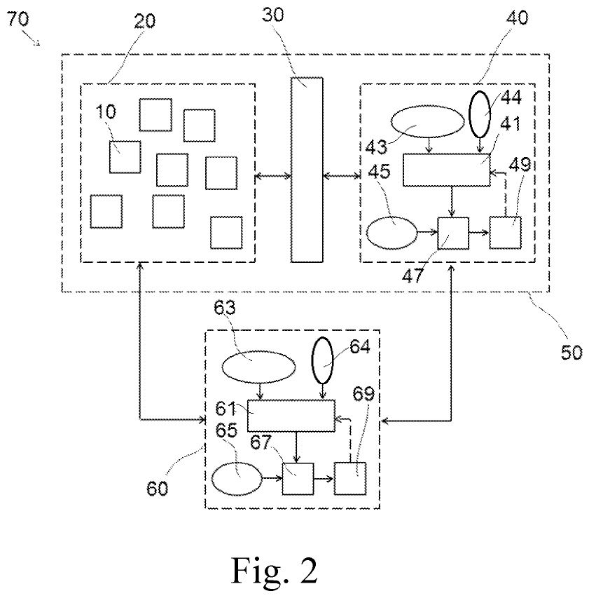

Reference is now made to FIG. 2 presenting a schematic diagram of exemplary system 70 for monitoring, controlling and predicting required maintenance in fluid control circuits. According to the present invention, system 70 has plurality of local portions 50 and central server 60 which can belong to a provider of the service of monitoring, controlling and predicting required maintenance in fluid control circuit (for clarity only one local portion 50 is shown). Each local portion 50 includes a plurality of elements 10, memory unit 30 and local data processing unit 40. As mentioned above, the sensed activity patterns of elements 10 belonging to plurality 20 are transmitted to memory unit 30 where the abovementioned patterns are stored. Local data processing unit 40 interrogates the memory unit, receives the data associated with monitoring the elements and analyzes the data and predicting required maintenance of the elements 10.

Local data processing unit 40 comprises a processor configured for interrogating the elements and receiving test data 45 and building a hypothesis 47 associated with performance of the elements by means of applying machine learning algorithm and/or statistical data modeling 41 and preloaded training data 43 in feedback therebetween. The processor is configured for collecting detected operation patterns of the elements belonging to the local arrangements, statistically analyzing the collected operation patterns, indicating operation patterns referring to emergency and planning predictive maintenance.

Service provider server 60 is able to duplicates at least one activity of the local data processing centers belonging to the local arrangements. Server 60 also collects detected operation patterns of the elements belonging to different local arrangements, statistically analyzes the collected operation patterns, and indicates operation patterns referring to emergency conditions and planning predictive maintenance. Hardware structure of service provider server is similar to the structure of local data processing unit 40. Specifically, service provider server 60 comprises a processor configured for interrogating the elements and receiving test data 65 and building a hypothesis 67 associated with performance of the elements by means of applying machine learning algorithm 61 and preloaded training data 63 in feedback therebetween. At least one of said local processing units 40 belonging to local portions 50 and service provider server 60 are configured to generate commands 44 and 64, respectively, to put into operation said actuator in response to recognizing said emergency events and to perform said preventive maintenance.

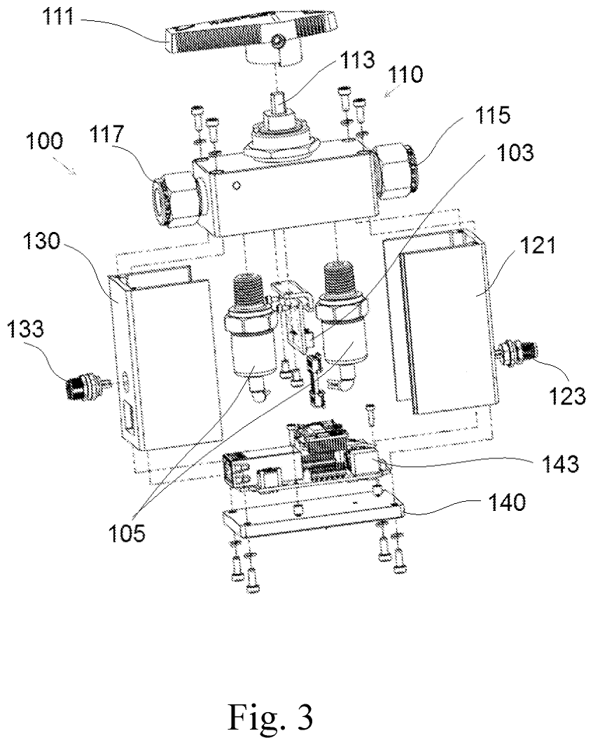

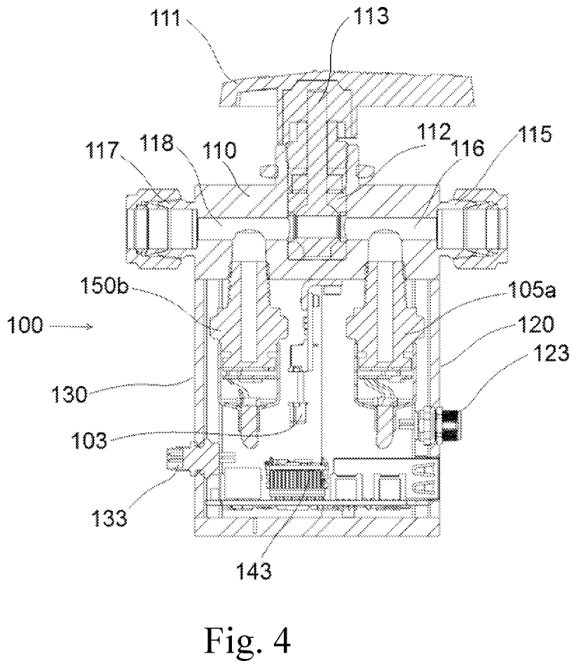

Reference is now made to FIGS. 3 and 4 presenting a controlling element embodied as a sensing valve 100. The aforesaid valve has inlet port 115 and outlet port 117 fluidly connected to valve passages 116 and 118, respectively. Control member 112 is rotationally mounted between passages 116 and 118 and positionable in open and closed positions. Numeral 111 refers to a handle for rotating stem 113 mechanically connected to control member 112. Stem 113 is manipulatable by an actuator (not shown). The actuator is selectaed from the group consisting of a hydraulic actuator, a pneumatic actuator, an electromagnetic actuator and any combination thereof.

Side walls 120 and 130 carry connectors 123 and 133, respectively, configured for connecting a signal cable for transferring sensed data to a service provider server and an actuator cable.

Sensing valve 100 is provided with 3 sensors, specifically, incoming pressure sensor 105a, outcoming pressure sensor 105b and temperature sensor 103. Sensors of fluid composition, fluid humidity, and flow rate, accelerometer and an environmental sensor are also in the scope of the present invention. Inlet and outlet sensor arrangements 105a and 105b are in fluid connection with inlet and outlet ports 116 and 118, respectively.

It should be emphasized that control member 112 embodied as a ball floating within valve body 110 is disclosed ad exemplum only. Sensors 105a, 105b and 103 are applicable to valves provided with any type of control members.

Sensors 105a, 105b and 103 are electrically coupled to microprocessor 143 which is configured for reporting at least one characteristic selected from the group consisting of inlet fluid pressure, inlet fluid temperature, inlet fluid humidity, inlet fluid chemical composition, outlet fluid pressure, outlet fluid temperature, outlet fluid humidity, outlet fluid chemical composition, differential pressure, differential temperature, differential humidity. The sensing valve 100 is provided with communication means configured for establishing a bidirectional connection with a central server (not shown). Microprocessor 143 can be connected to the central server by a protocol selected from the group consisting of a serial communication protocol (ModBus, Ethernet, USB or Rs485), a wireless local network, a wireless personal area network, a nearfield communication network, a low power wide area network or a cellular network(LTE, WiFi, LoRa, RFID, NFC).

The actuator can be activated by one of alternative commands such as a command generated by a remote controller, an user's manual command, a command generated by said microprocessor on the basis of the processed data.

Microprocessor 143 can be preprogrammed for reporting a fault status if said command to change a position of said control member does not result in a change in reported inlet and outlet fluid pressure. In addition, microprocessor 143 can be preprogrammed for reporting a cautioning status if said outlet fluid pressure is higher than said inlet fluid pressure (back pressure). In order to avoid an accident event, microprocessor 143 can be preprogrammed for transmitting a command such as opening is forbidden if said outlet fluid pressure is higher than said inlet fluid pressure and/or opening if said outlet fluid pressure is higher than said inlet fluid pressure only.

In addition, microprocessor 143 can be preprogrammed for reporting a cautioning status if said fluid pressure, relative humidity, and temperature measure within said inlet and outlet ports are equal. Similar to the back pressure situation, microprocessor 143 can be preprogrammed for transmitting a command such as opening is forbidden if said fluid pressure, relative humidity, and temperature measure within said inlet and outlet ports are equal and/or opening if said fluid pressure, relative humidity, and temperature measure within said inlet only.

As mentioned above, sensing valve 100 can be provided with an accelerometer placed within valve body 110. The accelerometer is configured for measuring accelerations applied to sensing valve 100. Microprocessor 143 can be preprogrammed for analyzing obtained acceleration values and reporting vibrations of sensing valve 100.

According to the present invention, a system for monitoring, a system for monitoring, controlling and predicting required maintenance in fluid control circuits is disclosed. The aforesaid system comprises: (a) a plurality of local arrangements; each local arrangement further comprising: (i) at least one controlling element configured to control a fluid flow; (ii) at least one monitoring element configured to monitor an operation pattern of the at least controlling element; (iii) a memory unit configured for storing the operation pattern of the at least controlling element; (iv) a local data processing unit configured for at least one activity selected from the group consisting of: interrogating the memory unit, analyzing the operation pattern of the at least controlling element, recognize emergency events therewithin and predicting required maintenance of the at least one controlling element and any combination thereof; (b) a service provider server configured for duplicating at least one activity of the local data processing units belonging to the local arrangements; the service provider server further configured for collecting detected operation patterns of the controlling elements belonging to the local arrangements, statistically analyzing the collected operation patterns, indicating operation patterns referring to emergency and preventive maintenance.

It is a core feature of the invention to provide at least one controlling element belonging to the local arrangements comprising an actuator configured to actuate the at least one controlling element; at least one of the local processing units belonging to the local arrangements and the service provider server are configured to generate commands to put into operation the actuator in response to recognizing the emergency events and to perform the preventive maintenance.

According to a further embodiment of the present invention, the controlling element is a valve.

According to a further embodiment of the present invention, monitoring element is a sensor configured for sensing activity of the controlling element.

According to a further embodiment of the present invention, each local arrangement comprises a transponder configured for transmitting the operation pattern sensed by the sensor to the memory unit and receiving the commands from the local data processing unit and service provider server.

According to a further embodiment of the present invention, the local data processing unit comprises a processor configured for interrogating the monitoring elements belonging to the local arrangements and receiving operation patterns and building a model of performance of the controlling elements by means of applying machine learning algorithm and preloaded training data in feedback therebetween.

According to a further embodiment of the present invention, the service provider server comprises a processor configured for interrogating the elements and receiving test data and building a hypothesis associated with performance of the elements by means of applying machine learning algorithm and preloaded training data in feedback therebetween; the processor is configured for collecting detected operation patterns of the elements belonging to the local arrangements, analyzing the collected operation patterns, indicating operation patterns referring to emergency and preventive maintenance.

According to a further embodiment of the present invention, the arrangements, memory units, local data processing units and service provider server are interconnected therebetween by a protocol selected from the group consisting of a wired serial communication protocol, a wireless local network, a wireless personal area network, a nearfield communication network, a low power wide area network, a cellular network and any combination thereof.

According to a further embodiment of the present invention, a method of monitoring, controlling and predicting required in fluid control circuits is disclosed. The aforesaid method comprising steps of: (a) providing a system further comprising: (i) a plurality of local arrangements; each local arrangement further comprising: (1) at least one controlling element configured to control a fluid flow; (2) at least one monitoring element configured to monitor an operation pattern of the at least controlling element; (3) a memory unit configured for storing the operation pattern of the at least controlling element; (4) a local data processing unit configured for at least one activity selected from the group consisting of: interrogating the memory unit, analyzing the operation pattern of the at least controlling element, recognize emergency events therewithin and predicting required maintenance of the at least one controlling element and any combination thereof; (i) a service provider server configured for duplicating at least one activity of the local data processing units belonging to the local arrangements; the service provider server further configured for collecting detected operation patterns of the controlling elements belonging to the local arrangements, statistically analyzing the collected operation patterns, indicating operation patterns referring to emergency and preventive maintenance; the at least one controlling element belonging to the local arrangements comprises an actuator configured to actuate the at least one controlling element; at least one of the local processing units belonging to the local arrangements and the service provider server are configured to generate commands to put into operation the actuator in response to recognizing the emergency events and to perform the preventive maintenance; (b) sensing activity of the elements; (c) transmitting sensed data to the memory unit; (d) interrogating the memory unit; (e) receiving the sensed data; (f) analyzing the sensed data; (g) predicting required maintenance; and (h) generating commands to put into operation the actuator in response to recognizing the emergency events and to perform the preventive maintenance.

According to a further embodiment of the present invention, the method comprises a step of indicating an emergency condition.

According to a further embodiment of the present invention, the method comprises a step of transmitting an emergency command of closing or opening the elements.

According to a further embodiment of the present invention, the method comprises a step of collecting detected operation patterns of the elements belonging to the local arrangements.

According to a further embodiment of the present invention, the method comprises a step of statistically analyzing the collected operation patterns.

According to a further embodiment of the present invention, the method comprises a step of indicating operation patterns referring to emergency and planning predictive maintenance.

1. A system for monitoring, controlling and predicting required maintenance in fluid control circuits; said system comprising:
a. a plurality of local arrangements; each local arrangement further comprising:
i. at least one controlling element configured to control a fluid flow;
ii. at least one monitoring element configured to monitor an operation pattern of said at least controlling element;
iii. a memory unit configured for storing said operation pattern of said at least controlling element;
iv. a local data processing unit configured for at least one activity selected from the group consisting of: interrogating said memory unit, analyzing said operation pattern of said at least controlling element, recognize emergency events therewithin and predicting required maintenance of said at least one controlling element and any combination thereof;
b. a service provider server configured for duplicating at least one activity of said local data processing units belonging to said local arrangements; said service provider server further configured for collecting detected operation patterns of said controlling elements belonging to said local arrangements, statistically analyzing said collected operation patterns, indicating operation patterns referring to emergency and preventive maintenance. wherein said at least one controlling element belonging to said local arrangements comprises an actuator configured to actuate said at least one controlling element; at least one of said local processing units belonging to said local arrangements and said service provider server are configured to generate commands to put into operation said actuator in response to recognizing said emergency events and to perform said preventive maintenance.

2. The system according to claim 1, wherein said controlling element is a valve.

3. The system according to claim 1, wherein said monitoring element is a sensor configured for sensing activity of said controlling element.

4. The system according to claim 3, wherein each local arrangement comprises a transponder configured for transmitting said operation pattern sensed by said sensor to said memory unit and receiving said commands from said local data processing unit and service provider server.

5. The system according to claim 1, wherein said local data processing unit comprises a processor configured for interrogating said monitoring elements belonging to said local arrangements and receiving operation patterns and building a model of performance of said controlling elements by means of applying machine learning algorithm and preloaded training data in feedback therebetween.

6. The system according to claim 1, wherein said service provider server comprises a processor configured for interrogating said elements and receiving test data and building a hypothesis associated with performance of said elements by means of applying machine learning algorithm and preloaded training data in feedback therebetween; said processor is configured for collecting detected operation patterns of said elements belonging to said local arrangements, analyzing said collected operation patterns, indicating operation patterns referring to emergency and preventive maintenance.

7. The system according to claim 1, wherein said arrangements, memory units, local data processing units and service provider server are interconnected therebetween by a protocol selected from the group consisting of a wired serial communication protocol, a wireless local network, a wireless personal area network, a nearfield communication network, a low power wide area network, a cellular network and any combination thereof.

8. A method of monitoring, controlling and predicting required in fluid control circuits; said method comprising steps of:
a. providing a system further comprising:
i. a plurality of local arrangements; each local arrangement further comprising:
1. at least one controlling element configured to control a fluid flow;
2. at least one monitoring element configured to monitor an operation pattern of said at least controlling element;
3. a memory unit configured for storing said operation pattern of said at least controlling element;
4. a local data processing unit configured for at least one activity selected from the group consisting of: interrogating said memory unit, analyzing said operation pattern of said at least controlling element, recognize emergency events therewithin and predicting required maintenance of said at least one controlling element and any combination thereof;
ii. a service provider server configured for duplicating at least one activity of said local data processing units belonging to said local arrangements; said service provider server further configured for collecting detected operation patterns of said controlling elements belonging to said local arrangements, statistically analyzing said collected operation patterns, indicating operation patterns referring to emergency and preventive maintenance. said at least one controlling element belonging to said local arrangements comprises an actuator configured to actuate said at least one controlling element; at least one of said local processing units belonging to said local arrangements and said service provider server are configured to generate commands to put into operation said actuator in response to recognizing said emergency events and to perform said preventive maintenance;
b. sensing activity of said elements;
c. transmitting sensed data to said memory unit;
d. interrogating said memory unit;
e. receiving said sensed data;
f. analyzing said sensed data;
g. predicting required maintenance;
h. generating commands to put into operation said actuator in response to recognizing said emergency events and to perform said preventive maintenance.

9. The method according to claim 8 comprising a step of indicating an emergency condition.

10. The method according to claim 8 comprising a step of transmitting an emergency command of closing or opening said elements.

11. The method according to claim 8 comprising a step of collecting detected operation patterns of said elements belonging to said local arrangements;

12. The method according to claim 6 comprising a step of statistically analyzing said collected operation patterns;

13. The method according to claim 8 comprising a step of indicating operation patterns referring to emergency and preventive maintenance.
